(19) United States
(12) Patent Application Publication
(10) Pub. No.: US 2018/0229496 A1
(43) Pub. Date: Aug. 16, 2018

(54) INKJET HEAD AND DRIVING METHOD BY THE SAME

(71) Applicant: TOSHIBA TEC KABUSHIKI KAISHA, Tokyo (JP)

(72) Inventor: Noriyuki Kikuchi, Mishima Shizuoka (JP)

(21) Appl. No.: 15/883,118

(22) Filed: Jan. 30, 2018

(30) Foreign Application Priority Data
Feb. 16, 2017 (JP) 2017-026700

(51) Int. Cl. B41J 2/045; B41J 2/14; B41J 2/16

(52) U.S. Cl. CPC B41J 2/0452; B41J 2/1433; B41J 2/14201; B41J 2/04581; H01L 41/042; B41J 2/04541; B41J 2/1618; B41J 2/1623; B41J 2/04588

(57) ABSTRACT

In accordance with an embodiment, an inkjet head comprises a pressure chamber, an actuator, a nozzle plate, and a head drive circuit. The pressure chamber accommodates ink. The actuator is arranged in correspondence with the pressure chamber. The nozzle plate has a nozzle communicating with the pressure chamber. The head drive circuit applies a drive pulse signal, which includes a first pulse for returning a volume of the pressure chamber after expansion, a second pulse for returning the volume of the pressure chamber after contraction, and a third pulse for returning the volume of the pressure chamber after contraction, to the actuator in such a manner that the second pulse is applied without providing a standby time before the first pulse, and the third pulse is applied without providing the standby time after the first pulse.

### CROSS-REFERENCE TO RELATED APPLICATION

This application is based upon and claims the benefit of priority from Japanese Patent Application No. P2017-026700, filed Feb. 16, 2017, the entire contents of which are incorporated herein by reference.

### FIELD

Embodiments described herein relate generally to an inkjet head and a driving method by the same.

### BACKGROUND

Conventionally, there is known a DRP waveform as a waveform of a drive signal for discharging an ink droplet from an inkjet head. The DRP waveform is composed of an expansion pulse (D) for returning a volume of a pressure chamber after expansion, a contraction pulse (P) for returning the volume of the pressure chamber back to an original size after contraction, and a standby time (R) between the expansion pulse and the contraction pulse. There is also known a method of outputting the contraction pulse continuously after the expansion pulse and then discharging the ink droplet from the inkjet head according to the drive signal of a driving waveform which takes the standby time.

If an amount of ink liquid discharged from the inkjet head is increased by using the drive signal of the driving waveform, there is a concern that discharge stability deteriorates.

### DESCRIPTION OF THE DRAWINGS

FIG. 1 is a perspective view illustrating a schematic constitution of an inkjet head;

FIG. 2 is an exploded perspective view of the inkjet head;

FIG. 3 is a sectional view taken along a line F3-F3 in FIG. 1;

FIG. 4 is a perspective view illustrating the constitution of main portions of the inkjet head;

FIG. 5 is a plan view of a nozzle plate of the inkjet head;

FIG. 6 is a waveform diagram illustrating a drive pulse signal for discharging one ink droplet;

FIG. 7 is a waveform diagram illustrating a drive pulse signal for discharging two ink droplets;

FIG. 8 is a waveform diagram illustrating a drive pulse signal for discharging five ink droplets.

FIG. 9 is a waveform chart illustrating a simulation result of ink pressure and ink flow velocity at the time the drive pulse signal shown in FIG. 8 is applied to an electrode;

FIG. 10 is a view illustrating conditions at the time of an actual test in order to obtain time relationship among a first pulse, a second pulse, and a third pulse; and

FIG. 11 is a diagram illustrating an experimental result for each condition shown in FIG. 10.

### DETAILED DESCRIPTION

In accordance with an embodiment, an inkjet head comprises a pressure chamber, an actuator, a nozzle plate, and a head drive circuit. The pressure chamber accommodates ink. The actuator is arranged in correspondence with the pressure chamber. The nozzle plate has a nozzle communicating with the pressure chamber. The head drive circuit applies a drive pulse signal, which includes a first pulse for returning a volume of the pressure chamber after expansion, a second pulse for returning the volume of the pressure chamber after contraction, and a third pulse for returning the volume of the pressure chamber after contraction, to the actuator in such a manner that the second pulse is applied without providing a standby time before the first pulse, and the third pulse is applied without providing the standby time after the first pulse.

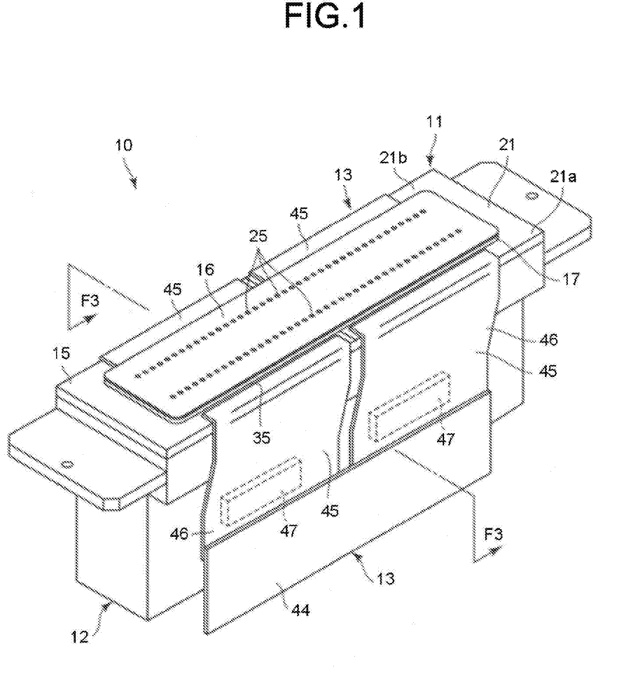

Hereinafter, an inkjet head according to an embodiment is described with reference to the accompanying drawings. Incidentally, in the present embodiment, a circulation-type inkjet head 10 (refer to FIG. 1) is exemplified.

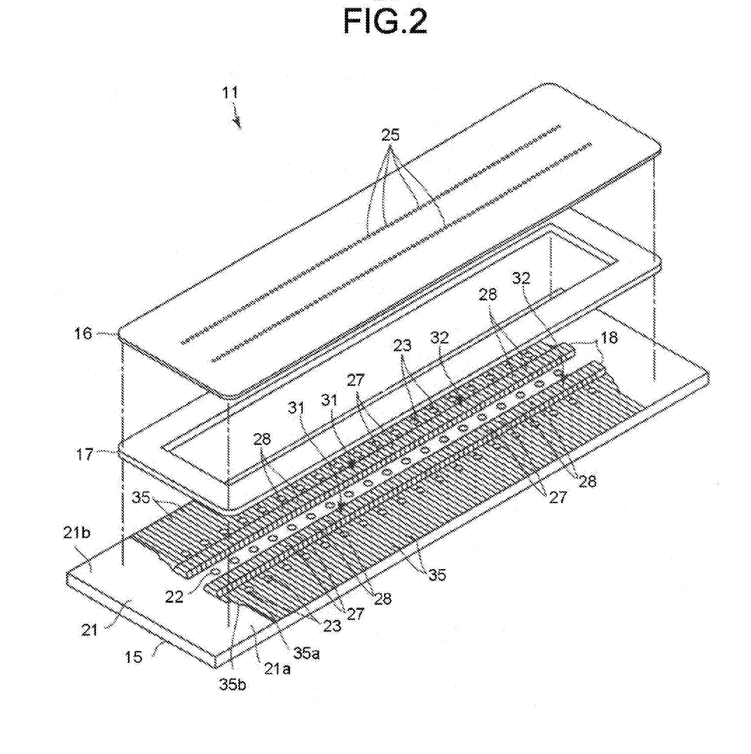

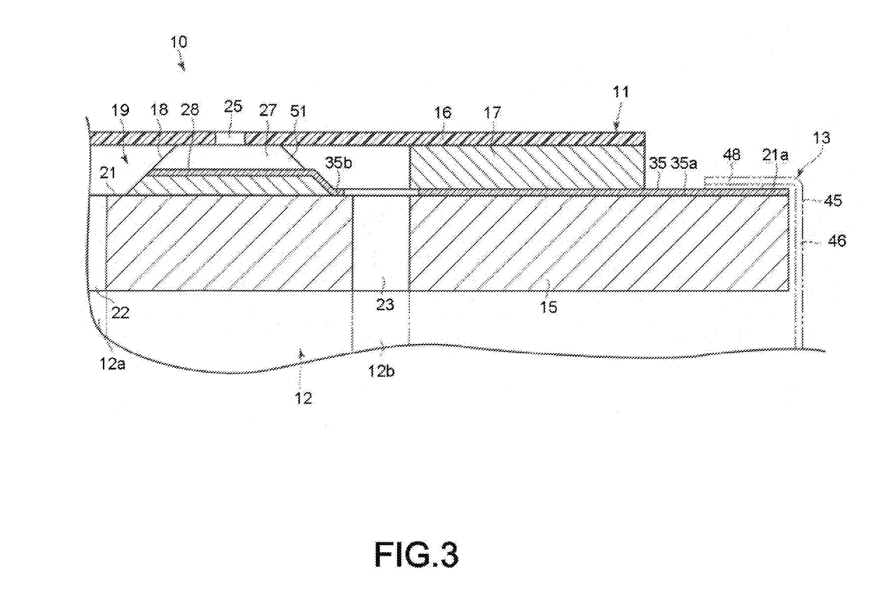

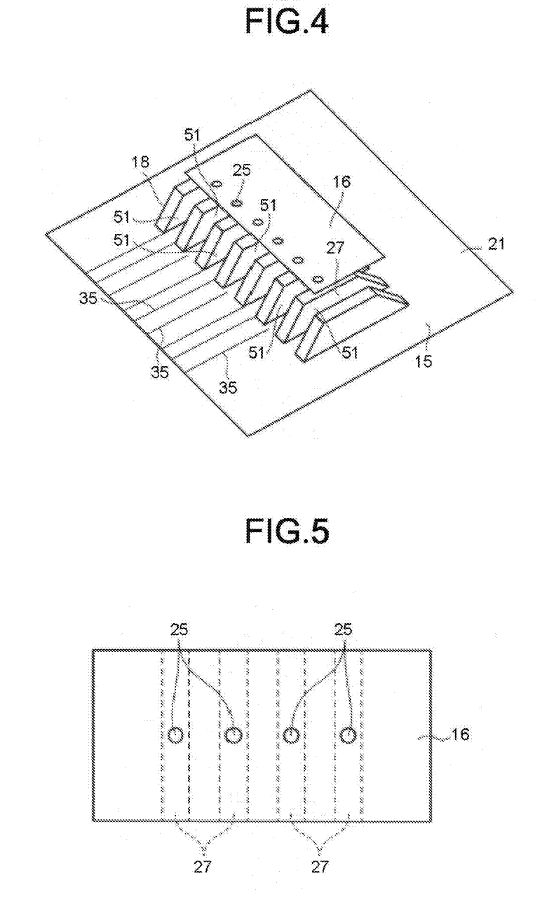

First, the constitution of the inkjet head 10 is described with reference to FIG. 1 to FIG. 5. FIG. 1 is a perspective view illustrating the inkjet head 10. FIG. 2 is an exploded perspective view of the inkjet head 10. FIG. 3 is a sectional view taken along a line F3-F3 in FIG. 1. FIG. 4 is a perspective view illustrating the constitution of the main portions of the inkjet head 10. FIG. 5 is a plan view of a nozzle plate 16 (refer to FIG. 3) of the inkjet head 10.

As shown in FIG. 1, the inkjet head 10 is a so-called side shooter type inkjet head. The inkjet head 10 is loaded on an inkjet printer, and is connected to an ink tank via components such as a tube. Such an inkjet head 10 includes a head main body 11, a unit section 12, and a pair of circuit boards 13.

The head main body 11 is used for discharging the ink. The head main body 11 is attached to the unit section 12. The unit section 12 includes a manifold forming a part of a path between the head main body 11 and the ink tank and a member for mounting at the inside of the inkjet printer. A pair of the circuit boards 13 is attached to the head main body 11, respectively.

As shown in FIG. 3, the head main body 11 includes a base plate 15, the nozzle plate 16, a frame member 17, and a pair of drive elements 18 (only one is shown in FIG. 3). The base plate 15 is an example of a base material. At the inside of the head main body 11, an ink chamber 19 to which the ink is supplied is formed.

As shown in FIG. 2, the base plate 15 is formed into a rectangular plate shape by ceramics such as alumina, for example. The base plate 15 has a flat mounting surface 21. A plurality of supply holes 22 and a plurality of discharge holes 23 are opened in the mounting surface 21.

The supply holes 22 are arranged side by side in a longitudinal direction of the base plate 15 at the center of the base plate 15. As shown in FIG. 3, the supply hole 22 communicates with an ink supply section 12a of the manifold of the unit section 12. The supply hole 22 is connected to the ink tank via the ink supply section 12a. The ink in the ink tank is supplied to the ink chamber 19 from the supply hole 22.

As shown in FIG. 2, the discharge holes 23 are arranged side by side in two rows so as to sandwich the supply hole 22 therebetween. As shown in FIG. 3, the discharge hole 23 communicates with an ink discharge section 12b of the manifold of the unit section 12. The discharge hole 23 is connected to the ink tank via the ink discharge section 12b. The ink in the ink chamber 19 is collected in the ink tank through the discharge hole 23. As a result, the ink circulates between the ink tank and the ink chamber 19.

As shown in FIG. 3, the nozzle plate 16 is formed by, for example, a rectangular film made of polyimide imparting a lyophobic function described later to the surface thereof. The nozzle plate 16 faces the mounting surface 21 of the base plate 15. The nozzle plate 16 is provided with a plurality of nozzles 25. The plurality of nozzles 25 is arranged in two rows along the longitudinal direction of the nozzle plate 16.

The frame member 17 is formed into a rectangular frame shape by, for example, a nickel alloy. The frame member 17 is interposed between the mounting surface 21 of the base plate 15 and the nozzle plate 16. The frame member 17 adheres to the mounting surface 21 and the nozzle plate 16, respectively. The nozzle plate 16 is attached to the base plate 15 via the frame member 17. The ink chamber 19 is formed by being surrounded by the base plate 15, the nozzle plate 16, and the frame member 17.

The drive element 18 is formed by two plate-like piezoelectric bodies formed by lead zirconate titanate (PZT), for example. The two piezoelectric bodies are bonded so that polarization directions thereof are opposite to each other in a thickness direction thereof.

The pair of the drive elements 18 adheres to the mounting surface 21 of the base plate 15. The pair of the drive elements 18 is arranged in parallel in the ink chamber 19 in correspondence with the nozzles 25 aligned in two rows. As shown in FIG. 3, the drive element 18 is formed in a trapezoidal cross section. The top of the drive element 18 adheres to the nozzle plate 16.

The drive element 18 is provided with a plurality of grooves 27. The grooves 27 extend in a direction crossing the longitudinal direction of the drive element 18, and are aligned in the longitudinal direction of the drive element 18. The plurality of grooves 27 faces the plurality of nozzles 25 of the nozzle plate 16 as shown in FIG. 5. The drive element 18 of the present embodiment is provided with a plurality of pressure chambers 51 that are driving flow paths for discharging the ink to the grooves 27 as shown in FIG. 4.

Electrodes 28 are provided in the plurality of grooves 27, respectively. The electrode 28 is formed, for example, by processing a nickel thin film by photoresist etching. The electrode 28 covers an inner surface of the groove 27.

From the mounting surface 21 of the base plate 15 to the drive element 18, as shown in FIG. 2, a plurality of wiring patterns 35 is provided. These wiring patterns 35 are formed, for example, by performing photoresist etching processing on a nickel thin film.

The wiring patterns 35 extend from one side end 21a and the other side end 21b of the mounting surface 21, respectively. The side ends 21a and 21b include not only an edge of the mounting surface 21 but also the peripheral region thereof. Therefore, the wiring pattern 35 may be provided inside the edge of the mounting surface 21.

Description of the wiring pattern 35 extending from one side end 21a is described below as a representative. The basic constitution of the wiring pattern 35 at the other side end 21b is the same as that of the wiring pattern 35 at the one side end 21a.

The wiring pattern 35 has a first portion 35a and a second portion 35b. As shown in FIG. 3, the first portion 35a of the wiring pattern 35 extends linearly from the side end 21a of the mounting surface 21 towards the drive element 18. The first portions 35a extend in parallel with each other. The second portion 35b of the wiring pattern 35 extends over an end of the first portion 35a and the electrode 28. The second portion 35b is electrically connected to the electrode 28, respectively.

In one drive element 18, several electrodes 28 among the plurality of electrodes 28 constitute a first electrode group 31. The other several electrodes 28 among the plurality of electrodes 28 constitute a second electrode group 32.

The first electrode group 31 and the second electrode group 32 are separated from each other at the center in the longitudinal direction of the drive element 18. The second electrode group 32 is adjacent to the first electrode group 31. The first and second electrode groups 31 and 32 include, for example, 159 electrodes 28, respectively.

As shown in FIG. 1, the pair of the circuit boards 13 has a board main body 44 and a pair of film carrier packages (FCP) 45, respectively. The FCP is also referred to as a tape carrier package (TCP).

The board main body 44 is a print wiring board formed into a rectangular shape and having rigidity. Various electronic components and connectors are mounted on the board main body 44. A pair of FCPs 45 is attached to the board main body 44, respectively.

The pair of FCPs 45 each have a flexible resin film 46 having a plurality of wirings formed thereon and a head drive circuit 47 connected to the plurality of wirings. The film 46 is a tape automated bonding (TAB). The head drive circuit 47 is an IC for applying a voltage to the electrode 28. The head drive circuit 47 is fixed to the film 46 by resin.

As shown in FIG. 3, the end of one FCP 45 is connected to the first portion 35a of a first wiring pattern 35 through thermocompression by an anisotropic conductive film (ACF) 48. The end of the other FCP 45 is connected to a first portion 36a of a second wiring pattern 36 through thermocompression by the ACF 48. Thus, the plurality of wirings of the FCP 45 is electrically connected to the first and second wiring patterns 35 and 36.

By connecting the FCP 45 to the first and second wiring patterns 35 and 36, the head drive circuit 47 is electrically connected to the electrode 28 via the wiring of the FCP 45. The head drive circuit 47 applies a voltage to the electrode 28 via the wiring of the film 46.

If the head drive circuit 47 applies the voltage to the electrode 28, the drive element 18 is deformed in a share mode, thereby increasing or decreasing the volume of the pressure chamber 51 provided with the electrode 28. As a result, the pressure of the ink in the pressure chamber 51 changes, and the ink is discharged from the nozzle 25. In this way, the drive element 18 separating the pressure chambers 51 becomes an actuator for applying a pressure vibration to the inside of the pressure chamber 51.

Below, a set of the pressure chamber 51, the electrode 28 and the nozzle 25 of the inkjet head 10 is referred to as a channel. The inkjet head 10 has channels ch. 1, ch. 2, . . . , Ch. N (in total of N) corresponding to the number of grooves 27.

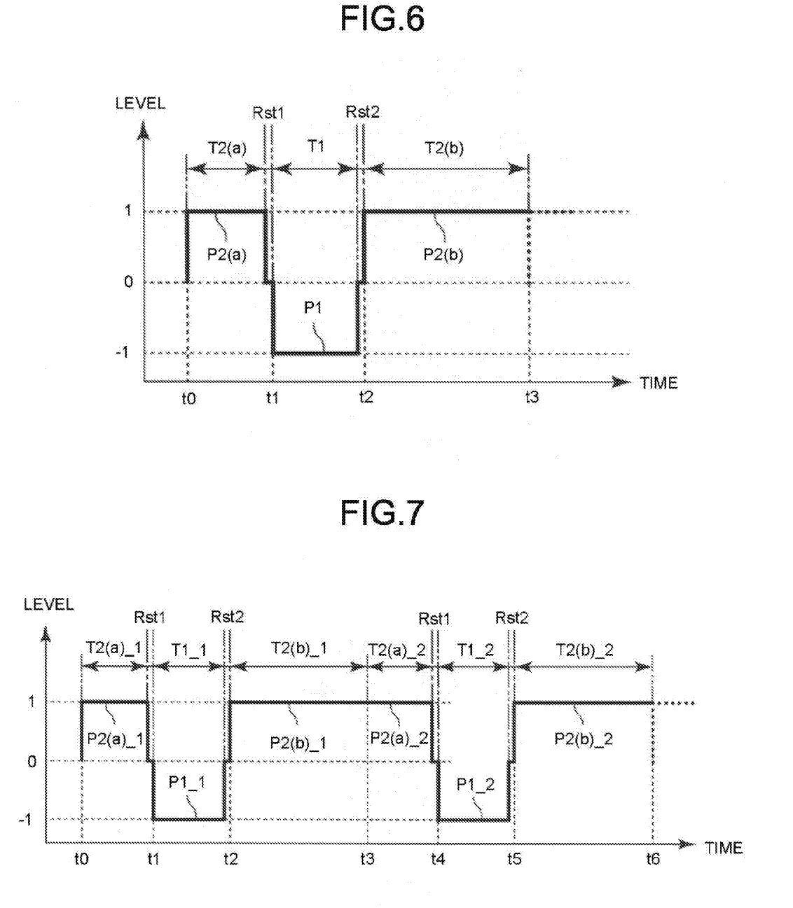

FIG. 6 is a view illustrating a drive pulse signal applied to the electrode 28 of a channel (discharge channel ch. x) for discharging the ink. This drive pulse signal is generated at the head drive circuit 47.

The drive pulse signal includes a first pulse P1, a second pulse P2(a), and a third pulse P2(b). The first pulse P1 is an expansion pulse for changing the electrode 28 of the discharge channel ch. x to a negative potential at a time point t1 to expand the volume of the pressure chamber 51 and then returning it to a ground potential after the elapse of a time T1. The second pulse P2(a) is a contraction pulse for changing the electrode 28 of the discharge channel ch. x to a positive potential at a time point t0 prior to the time point t1 to contract the volume of the pressure chamber 51 and then returning it to the ground potential after the elapse of a time T2(a). Between an end timing of the second pulse P2(a) and a start timing of the following first pulse P1, although an extremely short delay time Rst1 occurs, there is no standby time. Then, under the action of contraction by the second pulse P2(a), the ink droplet is not discharged from the nozzle 25 communicating with the pressure chamber 51. The third pulse P2(b) is a contraction pulse for changing the electrode 28 of the discharge channel ch. x to the positive potential at a time point t2 just after the first pulse P1 is ended to contract the volume of the pressure chamber 51 and then maintaining the contraction state thereof until the elapse of a time T2(b). Between an end timing of the first pulse P1 and a start timing of the following third pulse P2(b), although an extremely short delay time Rst2 occurs, there is no standby time. Then, due to the action of contraction by the third pulse P2(b), the ink droplet is discharged from the nozzle 25 communicating with the pressure chamber 51. The waveform in a section from the time point t0 to the time point t3 shows the drive pulse signal (discharge pulse signal) for discharging one ink droplet from the nozzle 25 of the discharge channel ch. x.

FIG. 7 is a waveform diagram of the drive pulse signal if two ink droplets are continuously discharged from the nozzle 25 of the discharge channel ch. x. In the same figure, a waveform of the pulses P2(a)_1, P1_1 and P2(b)_1 shown in the section from the time point t0 to the time point t3 is a drive pulse signal of the first droplet. The pulse P2(a)_1 is the second pulse P2(a), the pulse P1_1 is the first pulse P1, and the pulse P2(b)_1 is the third pulse P2(b). The waveform of the pulses P2(a)_2, P1_2, P2(b)_2 shown from the time point t3 to a time point t6 is a drive pulse signal of the second droplet. The pulse P2(a)_2 is the second pulse P2(a), the pulse P1_2 is the first pulse P1, and the pulse P2(b)_2 is the third pulse P2(b).

As shown in FIG. 7, there is no standby time between an end timing of the third pulse P2(b)_1 in the drive pulse signal for discharging the first droplet and a start timing of the second pulse P2(a)_2 in the drive pulse signal for discharging the second droplet. There is no delay time as well. Alternatively, even if a delay time Rst3 occurs, the time is extremely short. As a result, the pressure chamber 51 maintains the contraction state at about the time point t3.

The time relationship among the first pulse P1, the second pulse P2(a) and the third pulse P2(b) is described with reference to FIG. 7.

First, expansion state holding time T1_1 and expansion state holding time T1_2 of the pressure chamber 51 caused by the first pulses P1_1 and P1_2 are set to ½ of a natural vibration period of the pressure chamber 51. For example, if the natural vibration period is 4.7 μs, the expansion state holding time T1_1 and T1_2 are both 2.35 μs. At the start time points t1 and t4 of the first pulses P1_1 and P1_2, the partition walls 16a and 16b are displaced so that the volume of the pressure chamber 51 expands. Due to this displacement, a negative pressure is instantaneously applied to the vicinity of the nozzle 25 in the pressure chamber 51.

The pressure inside the pressure chamber 51 reverses from a negative pressure to a positive pressure with the natural vibration period after the expansion state holding time T1_1 and T1_2 elapse. At this moment, the first pulses P1_1 and P1_2 are terminated, and at the time points t2 and t5, the third pulses P2(b)_1 and P2(b)_2 are started continuously. With the start of the third pulses P2(b)_1 and P2(b)_2, the volume of the pressure chamber 51 shifts from the expansion state to a normal state and further to the contraction state at once. At this time, a positive pressure is instantaneously generated in the pressure chamber 51. With this pressure, a meniscus in the nozzle 25 starts moving forward.

The advance of the meniscus continues until a half of the natural vibration period elapses since the third pulses P2(b)_1 and P2(b)_2 are started. If a half of the natural vibration period elapses, the pressure of the vicinity of the nozzle 25 in the pressure chamber 51 changes from the positive pressure to the negative pressure again. As a result, the ink droplet is discharged separately from the ink in the nozzle 25.

Next, the contraction state holding time T2(a)_1 and T2(a)_2 of the pressure chamber 51 caused by the second pulses P2(a)_1 and P2(a)_2 and the contraction state holding time T2(b)_1 and T2(b)_2 of the pressure chamber 51 caused by the third pulses P2(b)_1 and P2(b)_2 are described.

In the present embodiment, a time width from the start timing (time point t1) of the first pulse P1_1 in the first cycle to the start timing (time point t4) of the first pulse P1_2 in the second cycle is set to be an even multiple of half of the natural vibration period. The time width from the time point t1 to the time point t4 is the total of the expansion state holding time T1_1 (half of the natural vibration period) of the first pulse P1_1 in the first cycle, the contraction state holding time T2(b)_1 of the third pulse P2(b)_1, the contraction state holding time T2(a)_2 of the second pulse P2(a)_2 in the second cycle, the delay time Rst1 from the end of the first pulse P1_1 in the first cycle to the start of the third pulse P2(b)_1, and the delay time Rst2 from the end of the second pulse P2(a)_2 in the second cycle to the start of the first pulse P1_2. The following equation (1) holds. In the equation (1), N represents a positive integer. Rst is the total of the delay time Rst1 and the delay time Rst2. Alternatively, Rst is the total of the delay time Rst1, the delay time Rst2 and the delay time Rst3 if the delay time Rst3 occurs.

T1_1+T2(b)_1+T2(a)_2+Rst=(2*N)*T1 (1)

The contraction state holding time T2(b)_1 of the third pulse P2(b)_1 in the first cycle and the contraction state holding time T2(a)_2 of the second pulse P2(a)_2 in the second cycle are determined so that the above equation (1) is established. By doing so, in a state in which the pressure vibration caused by instantaneously applying negative pressure to the inside of the pressure chamber 51 together with the start of the first pulse P1_1 in the first cycle is reversed to the negative pressure in the vicinity of the nozzle 25 in the pressure chamber 51 according to the natural vibration period, the first pulse P1_2 in the second cycle is started. As a result, an amplifying function occurs in the pressure vibration, and thus, a stronger pressure vibration towards the negative pressure side occurs.

Next, the time relationship between the expansion state holding time T1_2 of the first pulse P1_2 in the second cycle and the contraction state holding time T2(b)_2 of the third pulse P2(b)_2 is described.

In the present embodiment, a time width from the start timing (time point t4) of the first pulse P1_2 in the second cycle to the end timing (time point t6) of the third pulse P2(b)_2 is set to be an odd multiple of half of the natural vibration period. The time width from the time point t4 to the time point t6 is the total of the expansion state holding time T1_2 (half of the natural vibration period) of the first pulse P1_2, the contraction state holding time T2(b)_2 of the third pulse P2(b)_2, and the delay time Rst2 from the end of the first pulse P1_2 to the start of the third pulse P2(b)_2. The following equation (2) holds. In the equation (2), N represents a positive integer.

T1_2+T2(b)_2+Rst2=(2*N+1)*T1 (2)

The contraction state holding time T2(b)_2 of the third pulse P2(b)_2 is determined so that the above equation (2) is established. By doing so, in a state in which the pressure vibration caused by instantaneously applying the negative pressure to the inside of the pressure chamber 51 together with the start of the first pulse P1_2 in the second cycle is reversed to the positive pressure in the vicinity of the nozzle 25 in the pressure chamber 51 according to the natural vibration period, the third pulse P2(b)_2 is terminated. As a result, since the contracted pressure chamber 51 returns to an original state, a damping function of returning the pressure in the vicinity of the nozzle 25 tilted to the positive pressure side to the static pressure is generated, thereby providing the effect of canceling the pressure vibration.

Basically, the time widths of the pulse waveforms P1, P2(a) and P2(b) in the first and second cycles are equal. The following equation (3) holds.

T1_1=T1_2=2.35 μs

T2(a)_1=T2(a)_2

T2(b)_1=T2(b)_2 (3)

Therefore, the contraction state holding time T2(a)_1 and the contraction state holding time T2(a)_2 which are time widths of the second pulse P2(a), and the contraction state holding time T2(b)_1 and the contraction state holding time T2(b)_2 of the third pulse P2(b) are determined so that the relationships shown in the equations (1), (2) and (3) are established.

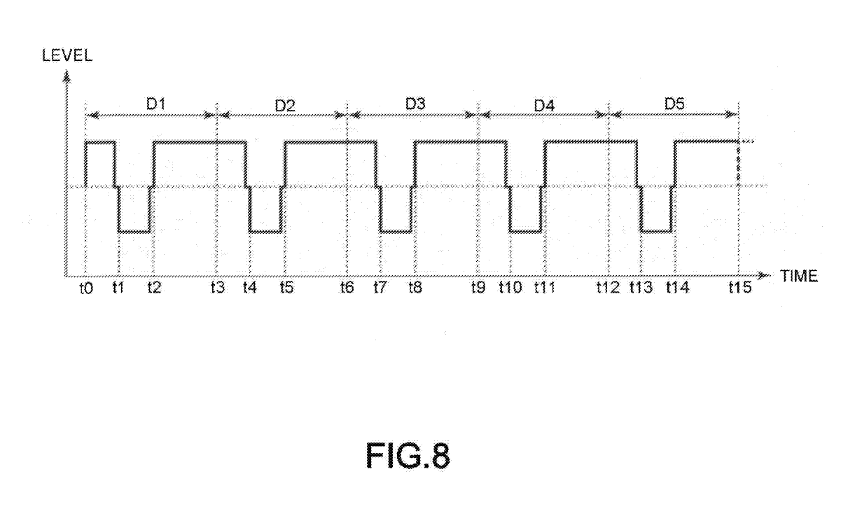

FIG. 8 shows an example at the time the maximum gradation value G is “5”. In FIG. 8, D1 to D5 indicate cycles in which one ink droplet is discharged. Basically, in all the cycles D1 to D5, the drive pulse signals composed of the first to third pulses P1, P2(a) and P2(b) are output. In FIG. 8, a section from the time point t0 to the time point t3 is the drive pulse signal for discharging the first drop of the ink droplet. Similarly, a section from the time point t3 to the time point t6 is the drive pulse signal for discharging the second drop of the ink droplet, a section from the time point t6 to the time point t9 is the drive pulse signal for discharging the third drop of the ink droplet, a section from the time point t9 to the time point t12 is the drive pulse signal for discharging the fourth drop of the ink droplet, and a section from the time point t12 to the time point t15 is the drive pulse signal for discharging the fifth drop of the ink droplet.

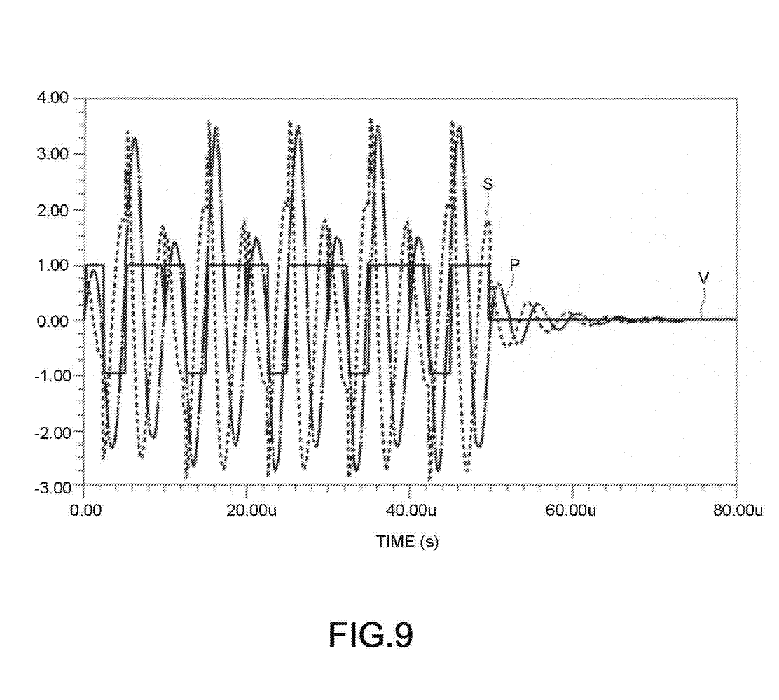

FIG. 9 is a waveform diagram illustrating a simulation result of ink pressure P and ink flow velocity S at the time a voltage V is applied to the electrode 28 of the pressure chamber 51 by the drive pulse signal shown in FIG. 8. As shown in FIG. 9, the ink pressure P and the ink flow velocity S are amplified from the end of the first pulse P1 to the start of the third pulse P2(b) from the first cycle to the fifth cycle. Then, the ink pressure P and the ink flow velocity S are attenuated after end of the third pulse P2(b) in the fifth cycle. There are two points where the ink pressure and the ink flow velocity respectively change in the positive direction in each cycle. Accordingly, the ink droplet discharged in each cycle becomes larger droplet.

The second pulse P2(a)_1 in the first cycle D1 becomes a boost pulse for giving momentum to the discharge of the first drop of the ink droplets. From the first pulse P1_1 in the first cycle D1 to the second pulse P2(a)_5 in the fifth cycle D5, it becomes a discharge pulse for obtaining an amplifying function. Further, the first pulse P1_5 to the third pulse P2(b)_5 of the fifth cycle D5 are discharge pulses for providing a canceling function.

In this manner, by applying the drive pulse signal of the present embodiment to the inkjet head 10 by the head drive circuit 47, not only is the discharge amount of the ink droplet along with the amplifying function of the discharge pulse increased, but also the discharge stability together with the canceling function can be obtained.

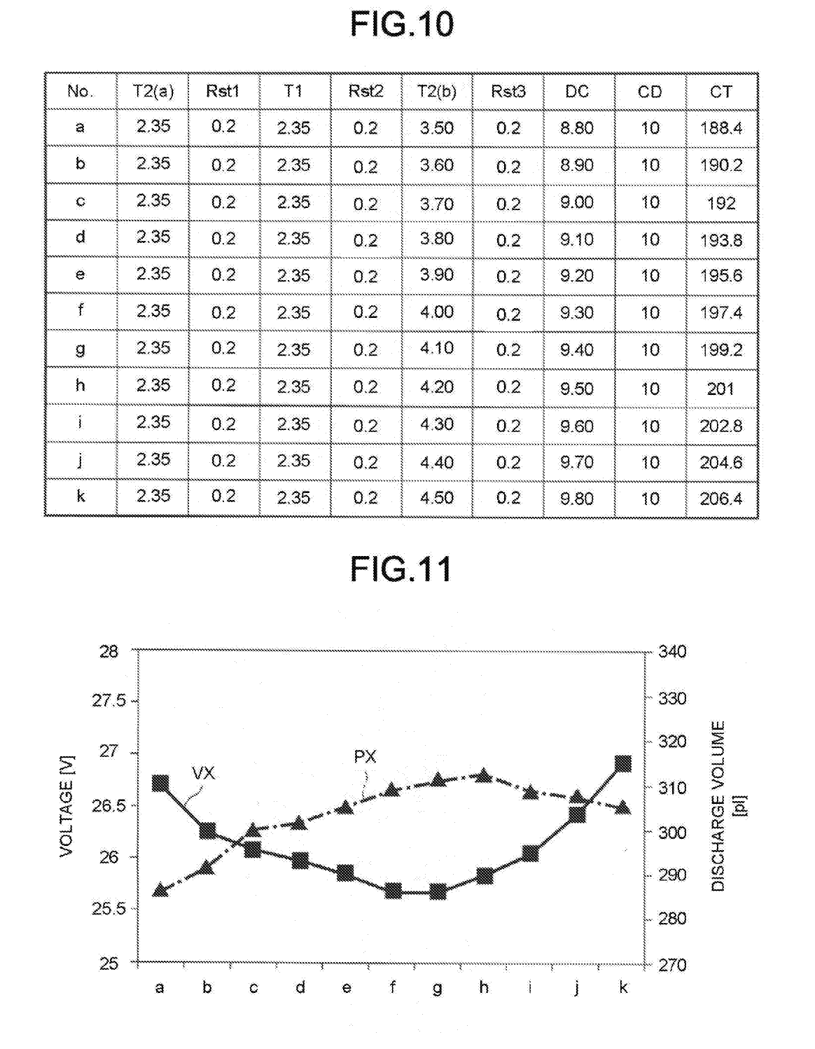

FIG. 10 shows the conditions at the time of actual test to determine the time relationship between the first pulse P1, the second pulse P2(a) and the third pulse P2(b). In FIG. 10, T2(a) is the time width of the second pulse P2(a), Rst1 is the delay time occurring at the time of shifting between the second pulse P2(a) and the first pulse P1, T1 is the time width of the first pulse P1, Rst2 is the delay time occurring at the time of shifting between the first pulse P1 and the third pulse P2(b), T2(b) is the time width of the third pulse P2(b), Rst3 is a delay time occurring at the time of shifting between the third pulse P2(b) and the second pulse P2(a), DC is a cycle of one drop, CD is a delay time between cycles, and CT is a cycle time. In the experiment, T2(a), Rst1, T1, Rst2 and Rst3 are common for the conditions a to k, and T2(b) is increased by 0.1 μs at a time.

FIG. 11 is a diagram illustrating experimental result under each condition shown in FIG. 10. In FIG. 11, a trajectory VX indicates an applied voltage for obtaining a predetermined discharge amount. Since the driving voltage for obtaining the same discharge amount is the lowest value, it becomes the condition in which the most discharge amount can be obtained. The trajectory PX indicates the discharge volume of the ink droplets. Among the conditions a to k, the condition g satisfies the equation (1), and at that time, a result that the discharge amount of the ink droplets is largely increased is obtained.

A modification of the embodiment is described below.

In the above embodiment, the circulation type inkjet head 10 is exemplified, but the present invention is not limited to the circulation type head. The present invention can also be applied to an inkjet head of a non-circulation type, for example, a head of a share mode and shared wall type.

While certain embodiments have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. An inkjet head, comprising:
a pressure chamber configured to accommodate ink;
an actuator in correspondence with the pressure chamber;
a nozzle plate having a nozzle in communication with the pressure chamber; and
a head drive circuit configured to apply a drive pulse signal, which comprises a first pulse for expanding and then returning a volume of the pressure chamber after expansion, a second pulse for contracting and then returning the volume of the pressure chamber after contraction, and a third pulse for contracting and then returning the volume of the pressure chamber after contraction, to the actuator so that the second pulse is applied without providing a standby time before the first pulse, and the third pulse is applied without providing the standby time after the first pulse.

2. The inkjet head according to claim 1, wherein
the head drive circuit repeatedly applies the drive pulse signal to the actuator corresponding to a number of the ink droplets discharged from the nozzle without providing the standby time between the third pulse in a previous cycle and the second pulse of a following cycle.

3. The inkjet head according to claim 2, wherein
a time width from a start timing of the first pulse to the end of the third pulse started continuously after the first pulse is an odd multiple of the time width of the first pulse.

4. The inkjet head according to claim 2, wherein
the time width from the start timing of the first pulse to the start timing of the first pulse in the next cycle is an even multiple of the time width of the first pulse.

5. The inkjet head according to claim 1, wherein the actuator comprises a pair of drive elements.

6. The inkjet head according to claim 5, wherein the pair of drive elements a plurality of grooves facing a plurality of nozzles of the nozzle plate.

7. The inkjet head according to claim 1, wherein the actuator comprises two plate-like piezoelectric bodies.

8. The inkjet head according to claim 7, wherein the two plate-like piezoelectric bodies have polarization directions opposite each other.

9. A driving method by an inkjet head, comprising:
applying a drive pulse signal, which comprises a first pulse for expanding and then returning a volume of a pressure chamber after expansion, a second pulse for contracting and then returning the volume of the pressure chamber after contraction, and a third pulse for contracting and then returning the volume of the pressure chamber after contraction, to an actuator provided corresponding to the pressure chamber for accommodating ink so that the second pulse is applied without providing a standby time before the first pulse, and the third pulse is applied without providing the standby time after the first pulse; and
discharging ink droplets from a nozzle communicating with the pressure chamber corresponding to the actuator.

10. The driving method according to claim 9, further comprising:
repeatedly applying the drive pulse signal to the actuator corresponding to a number of the ink droplets discharged from the nozzle without providing the standby time between the third pulse in a previous cycle and the second pulse of a following cycle.

11. The driving method according to claim 10, wherein
a time width from a start timing of applying the first pulse to the end of applying the third pulse started continuously after the first pulse is an odd multiple of the time width of the first pulse.

12. The driving method according to claim 10, wherein
the time width from the start timing of applying the first pulse to the start timing of applying the first pulse in the next cycle is an even multiple of the time width of the first pulse.

13. An inkjet printer, comprising:
an inkjet head, comprising:
a pressure chamber configured to accommodate ink;
an actuator in correspondence with the pressure chamber;
a nozzle plate having a nozzle in communication with the pressure chamber; and
a head drive circuit configured to apply a drive pulse signal, which comprises a first pulse for expanding and then returning a volume of the pressure chamber after expansion, a second pulse for contracting and then returning the volume of the pressure chamber after contraction, and a third pulse for contracting and then returning the volume of the pressure chamber after contraction, to the actuator so that the second pulse is applied without providing a standby time before the first pulse, and the third pulse is applied without providing the standby time after the first pulse.

14. The inkjet printer according to claim 13, wherein
the head drive circuit repeatedly applies the drive pulse signal to the actuator corresponding to a number of the ink droplets discharged from the nozzle without providing the standby time between the third pulse in a previous cycle and the second pulse of a following cycle.

15. The inkjet printer according to claim 14, wherein
a time width from a start timing of the first pulse to the end of the third pulse started continuously after the first pulse is an odd multiple of the time width of the first pulse.

16. The inkjet printer according to claim 14, wherein
the time width from the start timing of the first pulse to the start timing of the first pulse in the next cycle is an even multiple of the time width of the first pulse.

17. The inkjet printer according to claim 13, wherein the actuator comprises a pair of drive elements.

18. The inkjet printer according to claim 17, wherein the pair of drive elements a plurality of grooves facing a plurality of nozzles of the nozzle plate.

19. The inkjet printer according to claim 13, wherein the actuator comprises two plate-like piezoelectric bodies.

20. The inkjet printer according to claim 19, wherein the two plate-like piezoelectric bodies have polarization directions opposite each other.
